(19) United States
(12) Patent Application Publication
(10) Pub. No.: US 2012/0146042 A1
(43) Pub. Date: Jun. 14, 2012

(54) MICRO-CRYSTALLINE THIN FILM TRANSISTOR, DISPLAY DEVICE INCLUDING THE SAME AND MANUFACTURING METHOD THEREOF

(76) Inventors: Ki-Tae KIM, Seoul (KR); Sung-Ki Kim, Seoul (KR); Hong-Koo Lee, Goyang-si (KR); Jun-Hyeon Bae, Seoul (KR)

(21) Appl. No.: 13/269,348

(22) Filed: Oct. 7, 2011

(30) Foreign Application Priority Data
Dec. 8, 2010 (KR) 10-2010-0125110

(51) Int. Cl. H01L 33/08

(52) U.S. Cl. 257/72; 438/166; 257/E33.012

(57) ABSTRACT

A display device includes: a substrate; gate and data lines crossing each other on the substrate to define a pixel region; a thin film transistor that is connected to the gate and data lines, and includes a gate electrode, an active layer made of micro-crystalline silicon, and source and drain electrodes which are sequentially formed; a passivation layer on the thin film transistor; and a first electrode in the pixel region on the passivation layer and connected to the drain electrode, wherein a first overlap width between the drain electrode and the gate electrode is less than a second overlap width between the source electrode and the gate electrode.

The present invention claims the priority benefit of Korean Patent Application No. 10-2010-0125110, filed in Republic of Korea on Dec. 8, 2010, which is hereby incorporated by reference for all purposes as if fully set forth herein.

### BACKGROUND OF THE INVENTION

1. Field of the Invention

The present invention relates to a micro-crystalline thin film transistor, and more particularly, a micro-crystalline thin film transistor, a display device including the same and manufacturing method thereof.

2. Discussion of the Related Art

Until recently, display devices have typically used cathode-ray tubes (CRTs). Presently, many efforts and studies are being made to develop various types of flat panel displays, such as liquid crystal displays (LCDs), plasma display panels (PDPs), field emission displays (FEDs), and an organic electroluminescent displays (OELDs), as a substitute for CRTs. As these flat panel displays, active matrix type displays are widely used that includes a plurality of pixels arranged in a matrix form and each including a thin film transistor as a switching element.

The thin film transistor includes an active layer made of semiconductor such as silicon. Since amorphous silicon (a-Si:H) can be formed on a large-sized substrate such as a cheap glass substrate and processes therefor are simple, amorphous silicon is widely used.

However, the thin film transistor using amorphous silicon is slow in response time due to low field effect mobility thereof, and is difficult to drive at high speed for a large-sized display device.

Accordingly, a display device employing a thin film transistor using poly-crystalline silicon is suggested. In the display device using poly-crystalline silicon, a thin film transistor in a pixel region and a driving circuit can be formed on the same substrate, and an additional process of connecting the thin film transistor to the driving circuit is not needed, and thus processes are simple. Further, since poly-crystalline silicon has 100 times or 200 times the electric field mobility of amorphous silicon, poly-crystalline silicon is fast in response time and is stable in temperature and ray.

Polycrystalline silicon is formed by crystallizing amorphous silicon. In general, poly-crystalline silicon is formed by heat-treating amorphous silicon through a laser annealing using an Eximer laser. However, crystallization is slow because a narrow laser beam traverses and gradually scans a substrate with a plurality of shots in the annealing process, and polycrystalline silicon is not uniform depending on position because the shots of the laser beam are not uniform.

Recently, a technology that crystallizes amorphous silicon into micro-crystalline silicon (μc-Si) is suggested using an indirect thermal crystallization (ITC).

The ITC is a technology that forms micro-crystalline silicon by irradiating ray using a diode laser, converting an energy of the irradiated laser into a heat at a thermal converting layer, and then crystallizing amorphous silicon into micro-crystalline silicon using a high-temperature heat generated through the converting. Since an infrared laser is stable compared to an ultraviolet Eximer laser having a wavelength of about 308 nanometers and is capable of uniform crystallization, uniform property of element can be obtained.

FIG. 1 is a cross-sectional view illustrating a thin film transistor using micro-crystalline silicon according to the related art.

Referring to FIG. 1, a gate electrode 12 is on a substrate 10, and a gate insulating layer 16 is on the gate electrode 12. An active layer 20 is on the gate insulating layer 16, and an etch stopper 22 is on the active layer 20. The active layer 20 is made of micro-crystalline silicon. An ohmic contact layer 24 is on the etch stopper 22, and source and drain electrodes 32 and 34 is formed on the ohmic contact layer 24 and spaced apart from each other.

The thin film transistor including the active layer 20 made of micro-crystalline silicon has mobility and reliability more than a thin film transistor including an active layer made of amorphous silicon.

However, the micro-crystalline silicon thin film transistor has disadvantage that current property is relatively low in off state.

FIG. 2 is a graph illustrating current-voltage property of the micro-crystalline silicon thin film transistor. In FIG. 2, property of current (IDS) between source and drain electrodes to voltage (VGS) applied to a gate electrode with respect to a voltage (VD) applied to the drain electrode is expressed in logarithmic function.

Referring to FIG. 2, when VD is 10V, a leakage current occurs in off state. The leakage current causes contrast of a display device to be degraded.

### SUMMARY OF THE INVENTION

Accordingly, the present invention is directed to a micro-crystalline thin film transistor, a display device including the same and manufacturing method thereof which substantially obviates one or more of the problems due to limitations and disadvantages of the related art.

An advantage of the present invention is to provide a micro-crystalline thin film transistor, a display device including the same and manufacturing method thereof that can improve current property in off state and contrast property.

Additional features and advantages of the present invention will be set forth in the description which follows, and in part will be apparent from the description, or may be learned by practice of the invention. These and other advantages of the invention will be realized and attained by the structure particularly pointed out in the written description and claims thereof as well as the appended drawings.

To achieve these and other advantages and in accordance with the purpose of the present invention, as embodied and broadly described herein, a display device includes: a substrate; gate and data lines crossing each other on the substrate to define a pixel region; a thin film transistor that is connected to the gate and data lines, and includes a gate electrode, an active layer made of micro-crystalline silicon, and source and drain electrodes which are sequentially formed; a passivation layer on the thin film transistor; and a first electrode in the pixel region on the passivation layer and connected to the drain electrode, wherein a first overlap width between the drain electrode and the gate electrode is less than a second overlap width between the source electrode and the gate electrode.

In another aspect, a method of manufacturing a display device includes: forming a gate electrode and a gate line on a substrate; forming a gate insulating layer on the gate electrode and the gate line; forming a micro-crystalline silicon layer; forming an ohmic contact layer on the micro-crystalline silicon layer; forming source and drain electrodes on the ohmic contact layer; forming a passivation layer on the source and drain electrodes; and forming a first electrode on the passivation layer and connected to the drain electrode, wherein a first overlap width between the drain electrode and the gate electrode is less than a second overlap width between the source electrode and the gate electrode.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

In the drawings:

FIG. 1 is a cross-sectional view illustrating a thin film transistor using micro-crystalline silicon according to the related art;

FIG. 2 is a graph illustrating current-voltage property of the micro-crystalline silicon thin film transistor;

FIG. 3 is a cross-sectional view illustrating a micro-crystalline silicon thin film transistor according to a first embodiment of the present invention;

FIG. 4 is a view illustrating property, in off state, of the micro-crystalline silicon thin film transistor of FIG. 3;

FIG. 5 is a plan view illustrating a micro-crystalline silicon thin film transistor according to the second embodiment of the present invention;

FIG. 6 is a cross-sectional view illustrating an array substrate including the micro-crystalline thin film transistor according to the second embodiment of the present invention;

FIG. 7 is a circuit diagram of a pixel region of an organic electroluminescent display including the array substrate according to the second embodiment of the present invention;

FIGS. 8A to 8J are cross-sectional views illustrating a method of manufacturing the array substrate according to the present invention; and

FIG. 9 is a graph illustrating current-voltage property to first distance of a micro-crystalline silicon thin film transistor.

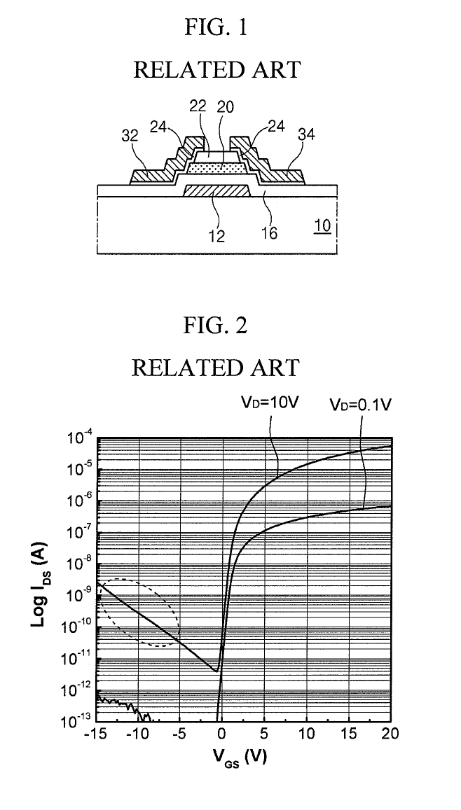

### DETAILED DESCRIPTION OF THE ILLUSTRATED EMBODIMENTS

Reference will now be made in detail to the illustrated embodiments of the present invention, which are illustrated in the accompanying drawings.

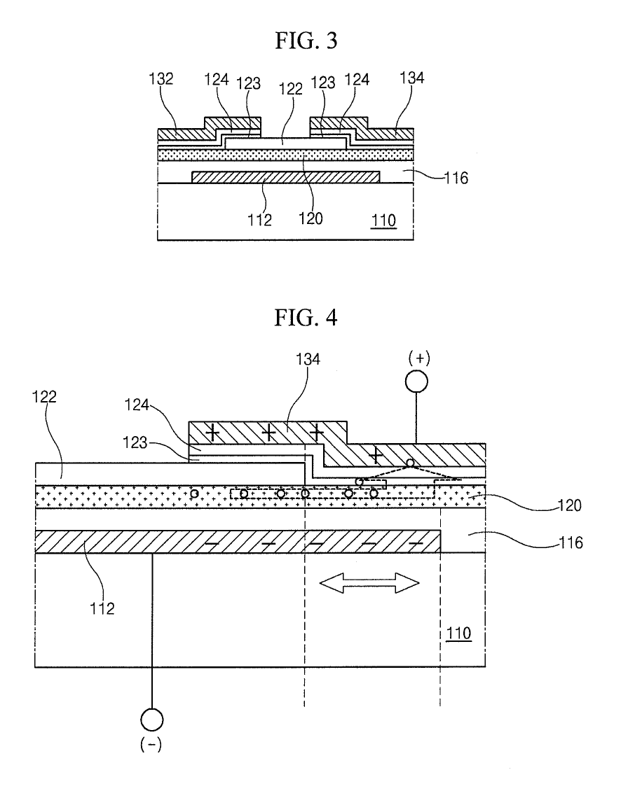

FIG. 3 is a cross-sectional view illustrating a micro-crystalline silicon thin film transistor according to a first embodiment of the present invention.

Referring to FIG. 3, a gate electrode 112 is formed on a substrate 110. The gate electrode 112 is formed of a conductive material such as metal. A gate insulating layer 116 is formed on the gate electrode 112.

An active layer 120 is formed on the gate insulating layer 116. Although not shown in the drawings, the active layer 120 has an in-plane pattern corresponding to the gate electrode 112. The active layer 120 is made of micro-crystalline silicon that is formed by crystallization of amorphous silicon using an infrared laser. An etch stopper 122 is formed on the active layer 120 and functions to prevent the active layer 120, which corresponds to a channel of a thin film transistor, from being etched.

An offset layer 123 and an ohmic contact layer 124 are sequentially formed on the etch stopper 122. The offset layer 123 is made of intrinsic amorphous silicon, and the ohmic contact layer is made of impurity-doped amorphous silicon. The offset layer 123 has a thickness of about 100 Å, and the ohmic contact layer 124 has a thickness of about 450 Å.

Source and drain electrodes 132 and 134 are formed on the ohmic contact layer 124 and made of a conductive material such as metal. The source and drain electrodes 132 and 134 are spaced apart from each other over the gate electrode 112, and overlap the active layer 120 and the gate electrode 112. The source and drain electrodes 132 and 134 has the same shape i.e., the same cross-sectional shape as the offset layer 123 and the ohmic contact layer 124, and edges thereof coincide.

The gate electrode 112, the active layer 120, and the source and drain electrodes 132 and 134 form the thin film transistor.

FIG. 4 is a view illustrating property, in off state, of the micro-crystalline silicon thin film transistor of FIG. 3. FIG. 4 enlarges a portion of FIG. 3 including the drain electrode 134.

Referring to FIG. 4, when a negative voltage is applied to the gate electrode 112 and a positive voltage is applied to the drain electrode 134, an electric field is formed where the gate electrode 112 and the drain electrode 134 overlap each other, and thus charges are accumulated at an interface of the active layer 120 over a region from an end of the gate electrode 112 to an end of the etch stopper 122 where the channel begins. The accumulated charges moves by an electric field due to a voltage difference between the source and drain electrodes 132 and 134, and thus leakage current occurs.

In the first embodiment, the offset layer 123 is configured between the active layer 120 and the ohmic contact layer 124, thus the offset layer 123 functions as a resistance layer, and thus the leakage current can be prevented.

Since the offset layer 123 is made of intrinsic amorphous silicon, and the ohmic contact layer 124 is made of impurity-doped amorphous silicon, the offset layer 123, the ohmic contact layer 124 may be sequentially formed in the same process chamber and a source gas may be added to dope the ohmic contact layer 124 with impurities in forming the ohmic contact layer 124. The impurities may be P (positive) type ions or N (negative) type ions. For example, in the first embodiment, a source gas including phosphor for doping with N type ions may be used.

To improve productivity, a process for one array substrate is repeated for array substrates of display devices in the process chamber, and then a cleaning process is performed. Accordingly, in the process chamber, intrinsic amorphous silicon and impurity-doped amorphous silicon are deposited on an array substrate, and then intrinsic amorphous silicon and impurity-doped amorphous silicon are deposited on the next array substrate.

In this case, the inside of the process chamber is contaminated by the source gas including phosphor used to deposit impurity-doped amorphous silicon, and thus phosphorus diffusion affects a following step of depositing intrinsic amorphous silicon. Accordingly, the offset layer 123 may be contaminated, and leakage current may not be completely prevented. Further, property of the offset layer 123 is varied according to other deposition conditions in the process chamber.

When a thickness of the offset layer 123 increases, this can reduce sensitivity to process but degrades mobility of a thin film transistor.

A second embodiment of the present invention improves current property in off state through structural change of a micro-crystalline silicon thin film transistor.

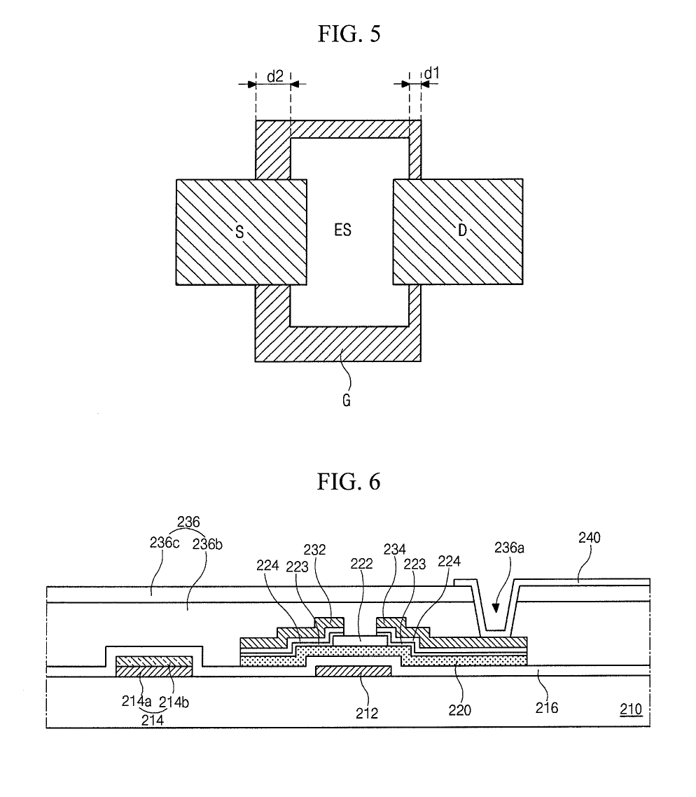

FIG. 5 is a plan view illustrating a micro-crystalline silicon thin film transistor according to the second embodiment of the present invention.

Referring to FIG. 5, source and drain electrodes S and D spaced apart form each other overlap a gate electrode G, and an etch stopper ES is formed between the source and drain electrodes S and D and the gate electrode G. An active layer (not shown) made of micro-crystalline silicon is formed between the gate electrode G and the etch stopper ES, and has a shape substantially identical to a shape made along edges of the source and drain electrodes S and D and the etch stopper ES. A portion of the active layer corresponding to the etch stopper ES acts as a channel of a thin film transistor.

The drain electrode D overlaps the gate electrode G with a first width, and the source electrode S overlaps the gate electrode G with a second width. The first width is less than the second width. Accordingly, a first distance d1 from an end of the gate electrode G overlapping the drain electrode G to an end of the channel i.e., to an end of the etch stopper ES is less than a second distance d2 from the other end of the gate electrode G overlapping the source electrode S to the other end of the channel i.e., to the other end of the etch stopper ES. For example, the first distance may be about 0 to 0.5 μm and the second distance d2 may be about 2 to 3 μm.

Accordingly, the source and drain electrodes S and D and the gate electrode G make an asymmetric overlap structure. Even though the source and drain electrodes S and D and the gate electrode G make a symmetric overlap structure by making the first and second distances identical, this causes mobility of a thin film transistor to be reduced.

However, in the second embodiment, the overlap width between the gate electrode G and the drain electrode D, which directly influences current property, in off state, of the micro-crystalline thin film transistor, is reduced so that the asymmetric structure is made. Accordingly, leakage current can be prevented, and current property in off state can be improved.

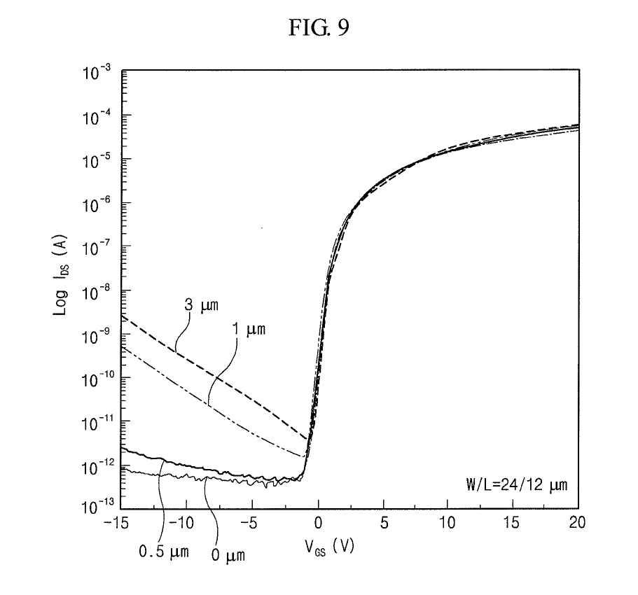

The advantage according to the second embodiment may be shown with reference to FIG. 9. FIG. 9 is a graph illustrating current-voltage property to first distance of a micro-crystalline silicon thin film transistor. Referring to FIG. 9, as the first distance decreases, leakage current in off state decreases. In particular, when the first distance is in a range of about 0 to 0.5 μm, the leakage current is critically reduced to the meaningful level. Accordingly, property of the micro-crystalline thin film transistor configured as above can be improved.

FIG. 6 is a cross-sectional view illustrating an array substrate including the micro-crystalline thin film transistor according to the second embodiment of the present invention.

Referring to FIG. 6, a gate electrode 212 and a gate line 214 are formed on a substrate 210. The gate electrode 212 and the gate line 214 are made of a conductive material such as metal. The substrate 212 may be transparent or opaque, and be made of glass or plastic. The gate electrode 212 may have a single-layered structure that is made of chromium, molybdenum, tungsten, titanium or the like, or alloy thereof. The gate line 214 may have a double-layered structure that includes a lower line layer 214a and an upper line layer 214b, and the lower line layer 214a may be made of chromium, molybdenum, tungsten, titanium or the like, or alloy thereof and the upper line layer 214b may be made of a material having low resistance such as copper or aluminum. For example, the gate electrode 212 and the lower line layer 214a are made of an alloy of molybdenum and titanium, and the upper line layer 214b is made of copper.

A gate insulating layer 216 is formed on the gate electrode 212 and the gate line 214. The gate insulating layer 216 may have a single-layered structure made of one of silicon oxide (SiO2) and silicon nitride (SiNx), or a double-layered structure made of silicon oxide (SiO2) and silicon nitride (SiNx).

An active layer 220 is formed on the gate insulating layer 216 corresponding to the gate electrode 212. The active layer 220 is made of micro-crystalline silicon that is formed by crystallizing amorphous silicon using an infrared laser.

An etch stopper 222 is formed on the active layer 220. The etch stopper 222 may be made of silicon oxide (SiO2) and functions to prevent the active layer 220 corresponding to a channel of a thin film transistor from being etched. The etch stopper 222 is located over the gate electrode 212, and edges of the etch stopper 222 are inside edges of the gate electrode 212. A portion of the active layer 220 corresponding to the etch stopper 222 functions as the channel of the thin film transistor.

An offset layer 223 and an ohmic contact layer 224 are sequentially formed on the etch stopper 222. The offset layer 223 is made of intrinsic amorphous silicon, and the ohmic contact layer 224 is made of impurity-doped amorphous silicon. It is preferred that the offset layer 223 has a thickness of about 50 Å or less, and alternatively, the offset layer 223 may be omitted.

Source and drain electrodes 232 and 234 are formed on the ohmic contact layer 224. The source and drain electrodes 232 and 234 may be formed of copper, aluminum, chromium, molybdenum, tungsten or the like, or an alloy thereof. Alternatively, the source and drain electrodes 232 and 234 may have a double-layered structure that includes a first layer made of copper or aluminum and a second layer made of other metal material or an alloy thereof. The source and drain electrodes 232 and 234 may have the same shape i.e., the same structure in cross-section as the ohmic contact layer 224, and edges of the source and drain electrodes 232 and 234 may coincide with edges of the ohmic contact layer 224.

The gate electrode 212, the active layer 220 and the source and drain electrodes 232 and 234 form the thin film transistor.

A passivation layer 236 is formed on the source and drain electrodes 232 and 234, and has a drain contact hole 236a exposing the drain electrode 234. The passivation layer 236 may have a double-layered structure that includes a first insulating layer 236b made of silicon oxide (SiO2) and a second insulating layer 236c made of silicon nitride (SiNx). Alternatively, the passivation layer 236 may have a single-layered structure, and be made of an organic material such as benzocyclobutene (BCB) or acrylic resin. It is preferred that the passivation layer 236 has a thickness to substantially eliminate steps of the substrate 210 due to the thin film transistor and a surface of the passivation layer 236 is substantially even.

A pixel electrode 240 is formed on the passivation layer 236, and contacts the drain electrode 234 through the drain contact hole 236a. The pixel electrode may be made of a transparent conductive material, for example, indium-tin-oxide (ITO), indium-zinc-oxide (IZO), or indium-tin-zinc-oxide (ITZO), or an opaque conductive material, for example, aluminum or chromium.

In the array substrate of the invention, since the active layer 220 of the thin film transistor is formed using the micro-crystalline silicon formed through the infrared laser, the display device capable of being driven at high speed and having uniform property can be manufactured. Further, since the asymmetric structure is made that the overlap width between the drain electrode 234 and the gate electrode 212 is less than the overlap width between the source electrode 232 and the gate electrode 212, current property in off state can be improved.

The array substrate according to the second embodiment can be employed for an organic electroluminescent display.

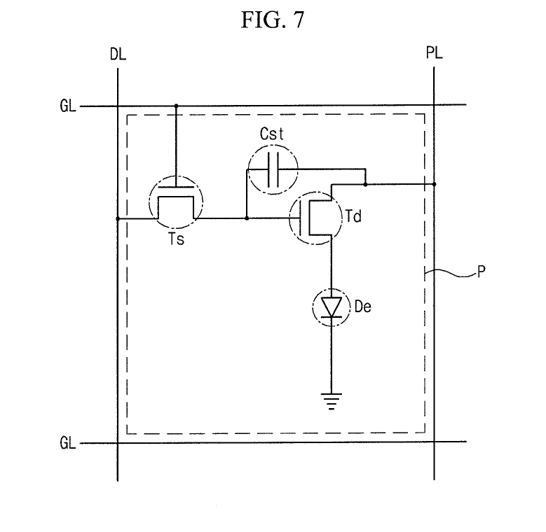

FIG. 7 is a circuit diagram of a pixel region of an organic electroluminescent display including the array substrate according to the second embodiment of the present invention.

Referring to FIG. 7, the organic electroluminescent display includes gate and data lines GL and DL crossing each other to define a pixel region P and a power line PL, and a switching thin film transistor Ts, a driving thin film transistor Td, a storage capacitor Cst, and a light emitting diode De are formed in the pixel region P.

The switching thin film transistor Ts is connected to the gate and data lines GL and DL, the driving thin film transistor Td and the storage capacitor Cst are connected to the switching thin film transistor Ts and the power line Pl, and the light emitting diode De is connected to the driving thin film transistor Td and a ground terminal.

Each of the switching thin film transistor Ts and the driving thin film transistor Td includes a gate electrode, an active layer, and source and drain electrodes, and the light emitting diode De includes first and second electrodes and an organic emitting layer between the first and second electrodes. The first and second electrodes of the light emitting diode De function as one and the other of anode and cathode.

The thin film transistor of FIG. 6 corresponds, to the driving thin film transistor Td, and the pixel electrode 240 corresponds to the anode of the light emitting diode De.

The switching thin film transistor may have a symmetric structure that each of the source and drain electrodes overlaps the gate electrode with the same width.

Operation to display images in the organic electroluminescent display is explained. The switching thin film transistor Ts is turned on according to a gate signal applied to the gate line GL, and a data signal applied to the data line DL is applied to the gate electrode of the driving thin film transistor Td and an electrode of the storage capacitor Cst through the switching thin film transistor Ts.

The driving thin film transistor Td is turned on according to the data signal applied to the gate electrode thereof, and accordingly, a current proportional to the data signal flows from the power line PL to the light emitting diode De through the driving thin film transistor Td, and the light emitting diode De emits light of brightness proportional to the current flowing through the driving thin film transistor Td.

The storage capacitor is charged with a voltage proportional to the data signal, and maintains a voltage of the gate electrode of the driving thin film transistor Td for a frame.

Accordingly, the organic electroluminescent display can display images using the gate and data signals.

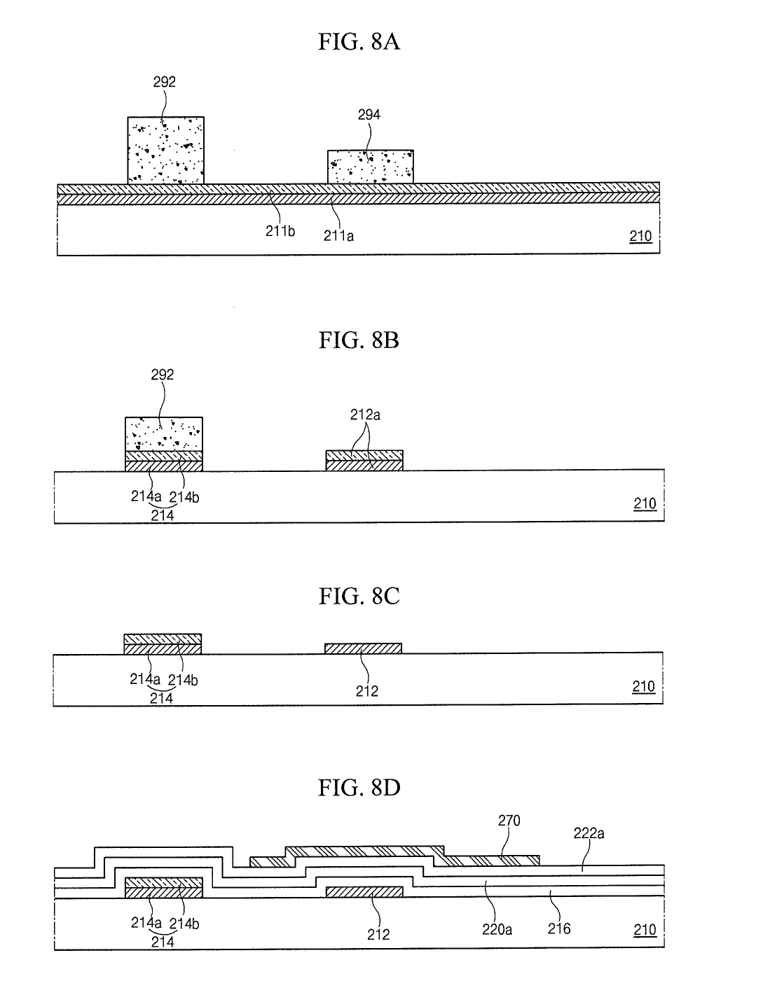

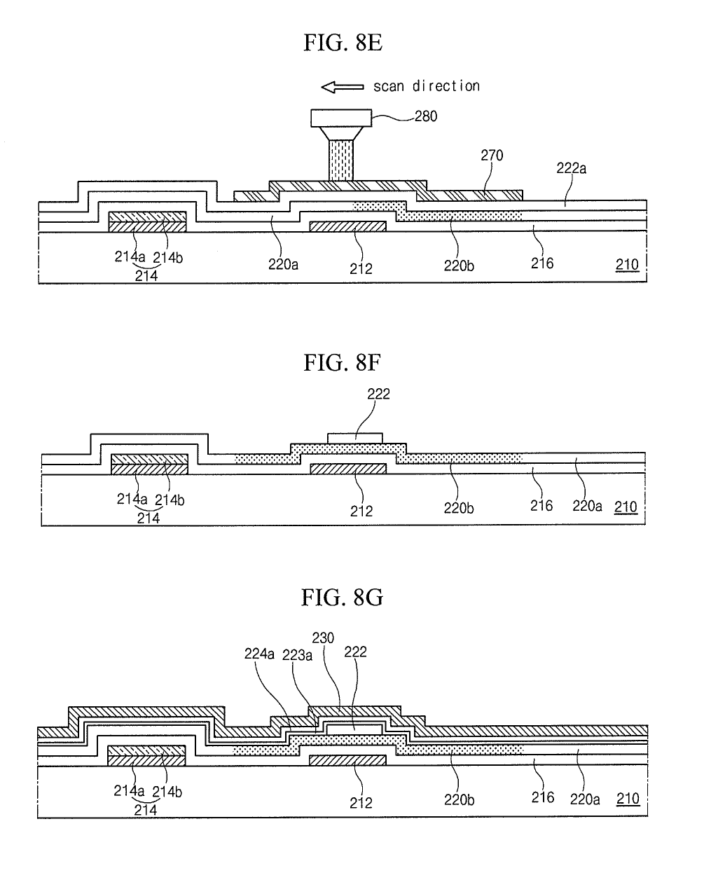

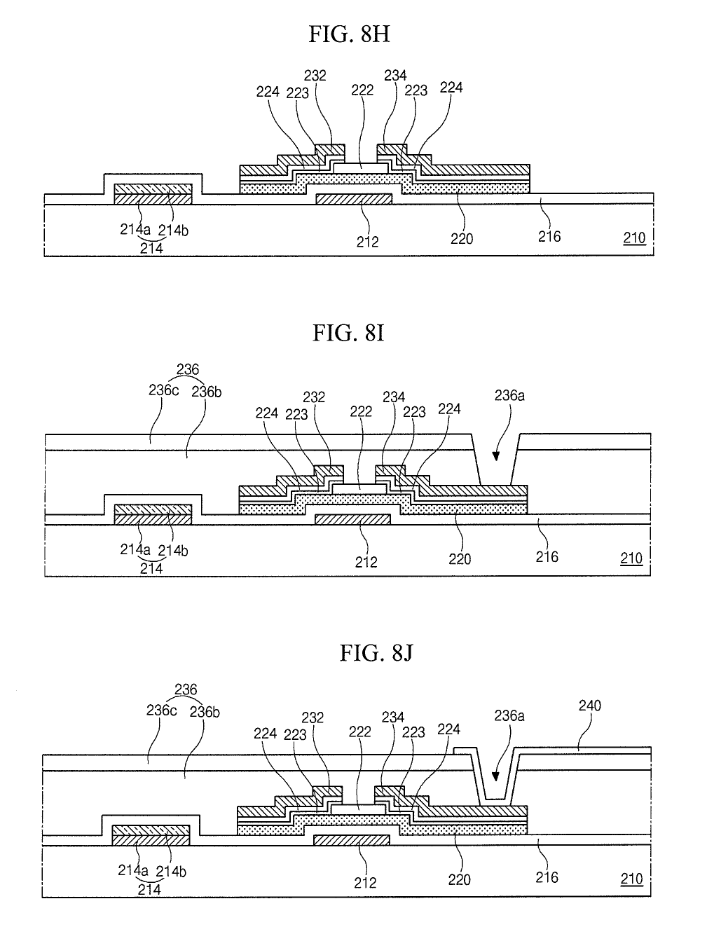

A method of manufacturing the array substrate according to the second embodiment is explained with reference to FIGS. 8A to 8J.

FIGS. 8A to 8J are cross-sectional views illustrating a method of manufacturing the array substrate according to the present invention.

Referring to FIG. 8A, first and second metal layers 211a and 211b are sequentially deposited on a substrate 210 with thicknesses of about 300 Å and about 2000 Å, respectively, then a photoresist material is deposited, light-exposed using a photo mask and developed to form first and second photoresist patterns 292 and 294 having different thicknesses. The photo mask includes a transmissive portion that completely transmits light, a blocking portion that completely blocks light, and a semi-transmissive portion that partially transmits light. The blocking portion corresponds to the first photoresist pattern 292, and the semi-transmissive portion corresponds to the second photoresist pattern 294. Accordingly, the second photoresist pattern 294 has a thickness less than that of the first photoresist pattern 292.

The substrate 210 may be transparent or opaque, and made of glass or plastic. The first metal layer 211a may be made of chromium, molybdenum, tungsten, titanium or the like, or alloy thereof. The second metal layer 211b may be made of copper or aluminum having a relatively low resistance. For example, the first metal layer 211a may be made of an alloy of molybdenum and titanium, and the second metal layer 211b may be made of copper.

Referring to FIG. 8B, the first and second metal layers 211a and 211b are patterned using the first and second photoresist patterns 292 and 294 as an etching mask. Accordingly, a gate line 214 is formed corresponding to the first photoresist pattern 292, and a gate electrode pattern 212a is formed corresponding to the second photoresist pattern 294. Then, a process such as an ashing is performed to remove the second photoresist pattern 294 and expose an upper layer of the gate electrode pattern 212a. In the ashing, the first photoresist pattern 292 is partially removed so that the thickness thereof is reduced.

Referring to FIG. 8C, the upper layer of the gate electrode pattern 212a is removed and then the first photoresist pattern is removed.

Accordingly, through one photolithography process, the gate electrode 212 of a single-layered structure made of molybdenum-titanium alloy, and the gate line 214 of a double-layered structure made of molybdenum-titanium alloy and copper are formed.

Referring to FIG. 8D, a gate insulating layer 216, an amorphous silicon layer 220a, and a buffer insulating layer 222a are sequentially formed. The gate insulating layer 216, the amorphous silicon layer 220a, and the buffer insulating layer 222a are formed collectively in the same process chamber using a plasma enhanced chemical vapor deposition (PECVD). The gate insulating layer 216 may have a single-layered structure of silicon nitride (SiNx) or silicon oxide (SiO2) or a double-layered structure of silicon nitride (SiNx) and silicon oxide (SiO2). The buffer insulating layer 222a is used for an etch stopper that prevents a channel of a thin film transistor from being etched, and is made of silicon oxide (SiO2). The buffer insulating layer 222a may have a thickness of about 100 Å to about 500 Å.

Then, a heat-converting layer 270, which absorbs an energy of an infrared laser, is formed on the buffer insulating layer 222a. The heat-converting layer may be formed of molybdenum. The heat converting layer 270 is formed by depositing molybdenum through a method such as a sputtering, and is patterned in order to selectively crystallizing a desired portion. Accordingly, the heat-converting layer 270 may be configured to only correspond to a position where the gate electrode 212 is formed, and to do not correspond to the gate line 214 that includes copper of bad heat-resistant property.

Since the heat-converting layer 270 is formed at the selective position, warpage or shrinkage of the substrate 210 due to heat occurring in a crystallizing process can be relieved.

Referring to FIG. 8E, the amorphous silicon layer 220a is crystallized through irradiation of an infrared laser 280. The infrared laser 280 performs scanning along a direction, for example, the infrared laser 280 scans and radiates in a direction from right to left on FIG. 8E. The heat-converting layer 270 radiated by the infrared laser 280 absorbs the energy of the infrared laser 280, and is crystallized into a micro-crystalline silicon by a heat occurring due to the absorption.

The infrared laser may have a wavelength of about 808 nm.

Referring to FIG. 8F, after the micro-crystalline silicon is formed at the desired region, the heat-converting layer 270 is removed, and the buffer insulating layer 222a is patterned in a photolithography process to form an etch stopper 222 corresponding to the gate electrode 212.

Referring to FIG. 8G, an intrinsic amorphous silicon layer 223a and an impurity-doped amorphous silicon layer 224a are sequentially formed on the etch stopper 222, and a conductive material such as metal is deposited to form a conductive material layer 230. The intrinsic amorphous silicon layer 223a prevents the impurity-doped amorphous silicon 224a from being stripped due to difference of stress in forming the impurity-doped amorphous silicon layer 224a. It is preferred that the intrinsic amorphous silicon layer 223a has a thickness of about 50 Å or less.

Referring to FIG. 8H, the conductive material layer 230, the impurity-doped amorphous silicon layer 224a, the intrinsic amorphous silicon layer 223a, and the amorphous and micro-crystalline silicon layers 220a and 220b are sequentially patterned through a photolithography process to form source and drain electrodes 232 and 234, an ohmic contact layer 224, an offset layer 223 and an active layer 220.

Accordingly, the source and drain electrodes 232 and 234 have the same shape i.e., the same structure in cross-section as the ohmic contact layer 224 and the offset layer 223, and edges thereof coincide. Further, the edges of the source and drain electrodes 232 and 234 coincide edges of the active layer 220.

As described above, the active layer 220 is formed in the same photolithography process of forming the source and drain electrodes 232 and 234. Alternatively, the active layer 220 may be formed in a photolithography process different from that of forming the source and drain electrodes 232 and 234, and be formed in the same photolithography process of forming the etch stopper 222.

The source and drain electrodes 232 and 234 may be made of copper, aluminum, chromium, molybdenum, tungsten or the like, or alloy thereof, or may have a double-layered structure that includes a first layer made of a metal material having a relatively low resistance such as copper or aluminum, and a second layer made of other metal material or alloy thereof.

An overlap width between the drain electrode 234 and the gate electrode 212 is less than an overlap width between the source electrode 232 and the gate electrode 212. In more detail, a distance from an end of the gate electrode 212 overlapping the drain electrode 234 to the channel i.e., the etch stopper 222 is less than a distance from the other end of the gate electrode 212 overlapping the source electrode 232 to the channel i.e., the etch stopper 222.

Although not shown in the drawings, a data line connected to the source electrode 232 is formed at the same process of forming the source and drain electrodes 232 and 234, and the data line crosses the gate line 214 to define a pixel region.

The gate electrode 212, the active layer 220, and the source and drain electrodes 232 and 234 form the thin film transistor.

Referring to FIG. 8I, a passivation layer 236 is formed on the source and drain electrodes 232 and 234. The passivation layer 236 is patterned in a photolithography process to form a drain contact hole 236a exposing the drain electrode 234. The passivation layer 236 may have a double-layered structure that includes a first insulating layer 236b made of silicon oxide (SiO2) and a second insulating layer 236c made of silicon nitride (SiNx). Alternatively, the passivation layer 236 may have a single-layered structure. Further, the passivation layer 236 may be made of an organic insulating material, for example, benzocyclobutene (BCB) or acrylic resin. It is preferred that the passivation layer 236 is configured to have a thickness to eliminate steps of the substrate 210 due to layers therebelow and a surface thereof is substantially even.

Referring to FIG. 8J, a conductive material is deposited on the passivation layer 236 and patterned to form a pixel electrode 240. The pixel electrode is located in the pixel region and contacts the drain electrode 234 through the drain contact hole 236a. The pixel electrode 240 may be made of a transparent conductive material, for example, indium-tin-oxide (ITO), indium-zinc-oxide (IZO), or indium-tin-zinc-oxide (ITZO), or an opaque conductive material, for example, aluminum or chromium.

As described in the above embodiments, the overlap area between the drain electrode and the gate electrode is less than the overlap area between the source electrode and the gate electrode. Accordingly, current property can be improved with maintaining electric field mobility. Further, reduction of contrast of the display device is prevented and display property can be improved.

It will be apparent to those skilled in the art that various modifications and variations can be made in the present invention without departing from the spirit or scope of the invention. Thus, it is intended that the present invention cover the modifications and variations of this invention provided they come within the scope of the appended claims and their equivalents.

What is claimed is:

1. A display device, comprising:
a substrate;
gate and data lines crossing each other on the substrate to define a pixel region;
a thin film transistor that is connected to the gate and data lines, and includes a gate electrode, an active layer made of micro-crystalline silicon, and source and drain electrodes which are sequentially formed;
a passivation layer on the thin film transistor; and
a first electrode in the pixel region on the passivation layer and connected to the drain electrode,
wherein a first overlap width between the drain electrode and the gate electrode is less than a second overlap width between the source electrode and the gate electrode.

2. The device according to claim 1, further comprising etch stopper configured to prevent the active layer from being etched, wherein a portion of the active layer corresponding to the etch stopper acts as a channel of the thin film transistor, and in the thin film transistor, a first distance from an end of the gate electrode overlapping the drain electrode to the channel is less than a second distance from the other end of the gate electrode overlapping the source electrode to the channel.

3. The device according to claim 1, wherein the first distance is about 0 to 0.5 micrometers, and the second distance is about 2 to 3 micrometers.

4. The device according to claim 1, further comprising:
an organic emitting layer and a second electrode, wherein the organic emitting layer located between the first electrode and the second electrode.

5. The device according to claim 1, wherein the passivation layer includes a first insulating layer made of silicon oxide (SiO2) and a second insulating layer made of silicon nitride (SiNx), or the passivation layer has a single-layered structure.

6. The device according to claim 1, wherein the gate electrode has a single-layered structure made of a first metal material, and the gate line has a double layered structure that includes a lower layer made of the first metal material and an upper layer made of material having resistance lower than the lower layer.

7. The device according to claim 6, wherein the first metal material includes chromium, molybdenum, tungsten, titanium or alloy thereof.

8. The device according to claim 6, wherein the material of the upper layer includes copper or aluminum.

9. The device according to claim 1, wherein the thin film transistor further includes an offset layer made of intrinsic amorphous silicon and an ohmic contact layer of impurity-doped amorphous silicon which are between the active layer and the source and drain electrodes.

10. The device according to claim 9, wherein the offset layer has a thickness of about 50 Å.

11. A method of manufacturing a display device, the method comprising:
forming a gate electrode and a gate line on a substrate;
forming a gate insulating layer on the gate electrode and the gate line;
forming a micro-crystalline silicon layer on the gate insulating layer;
forming an ohmic contact layer on the micro-crystalline silicon layer;
forming source and drain electrodes on the ohmic contact layer;
patterning the micro-crystalline silicon layer to form an active layer;
forming a passivation layer on the source and drain electrodes; and
forming a first electrode on the passivation layer and connected to the drain electrode,
wherein a first overlap width between the drain electrode and the gate electrode is less than a second overlap width between the source electrode and the gate electrode.

12. The method according to claim 11, wherein the step of forming the micro-crystalline silicon layer includes:
forming an amorphous silicon layer on the gate insulating layer;
forming a heat-converting layer on the amorphous silicon layer;
radiating infrared laser on the heat-converting layer to crystallize the amorphous silicon layer into the micro-crystalline silicon layer; and
removing the heat-converting layer on the micro-crystalline silicon layer.

13. The method according to claim 12, further comprising:
forming the buffer insulating layer between the amorphous silicon layer and the heat-converting layer, which will be pattered to be a etch stopper, wherein a portion of the active layer corresponding to the etch stopper acts as a channel of the thin film transistor, and a first distance from an end of the gate electrode overlapping the drain electrode to the channel is less than a second distance from the other end of the gate electrode overlapping the source electrode to the channel.

14. The method according to claim 11, wherein the gate electrode is formed to be a single-layered structure made of a first metal material, and the gate line includes a lower layer made of the first metal material and an upper layer made of material having resistance lower than the lower layer.

15. The method according to claim 14, wherein the first metal material includes chromium, molybdenum, tungsten, titanium or alloy thereof.

16. The method according to claim 14, wherein the material of the upper layer includes copper or aluminum.

17. The method according to claim 12, wherein the gate electrode and the gate line are formed in the same photolithography process using a photo mask that includes a transmissive portion, a blocking portion and a semi-transmissive portion, wherein the gate electrode has a single-layered structure made of a first metal material, and wherein the gate line has a double-layered structure made of the first metal material and copper.

18. The method according to claim 17, wherein the heat-converting layer is selectively patterned and spaced apart from the gate line.

19. The method according to claim 11, further comprising forming an offset layer made of intrinsic amorphous silicon between the ohmic contact layer and the active layer.

20. The method according to claim 19, wherein the offset layer has a thickness of about 50 Å.

21. The method according to claim 18, wherein the active layer, the ohmic contact layer, and the source and drain electrodes are formed in the same photolithography process.

22. The method according to claim 13, wherein the gate insulating layer, the amorphous silicon layer, and the buffer insulating layer are formed in the same process chamber.
